(19) United States
(12) Patent Application Publication
(10) Pub. No.: US 2025/0334632 A1
(43) Pub. Date: Oct. 30, 2025

(54) TEST HEAD

(71) Applicant: TSE CO., LTD., Cheonan-si (KR)

(72) Inventors: Young Hun JU, Cheonan-si (KR); Yoon Young JIN, Cheonan-si (KR); Sin Jae KIM, Cheonan-si (KR)

(73) Assignee: TSE CO., LTD., Cheonan-si (KR)

(21) Appl. No.: 19/185,859

(22) Filed: Apr. 22, 2025

(30) Foreign Application Priority Data
Apr. 30, 2024 (KR) 10-2024-0057993
Jul. 23, 2024 (KR) 10-2024-0096910

(51) Int. Cl. G01R 31/28; G01R 1/067; G01R 1/073

(52) U.S. Cl. CPC G01R 31/2886; G01R 1/06716; G01R 1/07342

(57) ABSTRACT

Disclosed is a test head including a probe located in the form of a pin from a semiconductor substrate toward a space converter, the probe having a displacement portion and an elastic portion located near the space converter and the semiconductor substrate, respectively, and a lower plate and an upper plate sequentially located in a longitudinal direction of the probe, the lower plate and the upper plate being configured to surround the displacement portion, wherein the probe has a “C” shape or an inverted “C” shape at the displacement portion.

### CROSS-REFERENCE TO RELATED APPLICATIONS

This application claims priority to Korean Patent Application No. 10-2024-0057993, filed on Apr. 30, 2024, and Korean Patent Application No. 10-2024-0096910, filed on Jul. 23, 2024, the entire contents of which are herein incorporated by reference.

### BACKGROUND OF THE INVENTION

### 1. Field of the Invention

The present invention relates to a test head configured such that, when a semiconductor substrate is located under a space converter of a probe card, the test head is located between the space converter and the semiconductor substrate so as to be in contact with an electrical pad of the space converter and a substrate pad of the semiconductor substrate.

### 2. Description of the Related Art

In general, an electrical die sorting (EDS) process is performed between a semiconductor front-end process and a semiconductor back-end process. Here, the semiconductor front-end process is performed to repeatedly form semiconductor chips on a semiconductor substrate. The semiconductor back-end process is performed to cut the semiconductor substrate into semiconductor chips and to package the semiconductor chips.

In addition, the EDS process is performed to check the electrical operation of the semiconductor chips on the semiconductor substrate. That is, the EDS process is performed to inspect the electrical operation of the semiconductor chips through a probe card in the state in which a probe card and the semiconductor substrate are mounted on an electrical test device.

Specifically, conventionally, as shown in FIG. 1, a probe card 460 has a test head 75 and a space converter 450, which are sequentially stacked. The test head 75 includes probes 30 and lower and upper plates 50 and 70 configured to surround each individual probe 30.

During the EDS process, the test head 75 is mounted on an electrical test device (not shown) through the probe card 460 along with the space converter 450 so as to be in contact with the space converter 450 and a semiconductor substrate 480. The test head 75 has a plurality of probes 30 extending through lower guide holes 45 of the lower plate 50 and upper guide holes 85 of the upper plate 70 in the lower and upper plates 50 and 70.

In FIG. 1, the probe 30 has a probing tip (not shown), an elastic portion 5, a displacement portion 18, and a probing head 25 sequentially provided in a longitudinal direction of the probe 30.

Although not shown, the probe 30 comes into contact with a substrate pad 475 of the semiconductor substrate 480 through the probing tip, comes into contact with an electric pad 445 of the space converter 450 through the probing head 25, and is pressed through the space converter 450 and the semiconductor substrate 480 to cause the buckling of the elastic portion 5.

In this case, the substrate pad 475 is located at a semiconductor chip (not shown) on the semiconductor substrate 480. During the buckling of the elastic portion 5 of the probe 30 between the space converter 450 and the semiconductor substrate 480, the probe 30 three-dimensionally moves in the lower guide hole 65 of the lower plate 50 and the upper guide hole 85 of the upper plate 70.

In addition, considering FIGS. 1 and 2, the probe 30 has two displacement holes 14 formed in the displacement portion 18. Considering FIGS. 1 and 2, the displacement portion 18 has a displacement hole 14 located straight along the displacement portion 18. In FIG. 2, the probe 30 has a “U”-shaped groove G1 formed in the displacement portion 18 and the probing head 25 along one side wall of the probe 30.

In FIG. 2, the probe 30 connects both side walls located around the displacement hole 14 of the displacement portion 18 and both side walls curved into the “U”-shaped groove G1 so as to be at an angle to each other. During buckling of the elastic portion 5 of the probe 30 between the space converter 450 and the semiconductor substrate 480, the displacement portion 18 is also curved due to the movement of the lower plate 50 relative to the upper plate 70, as shown in FIG. 3.

At this time, the displacement portion 18 moves through the lower guide hole 45 of the lower plate 50 and the upper guide hole 85 of the upper plate 70, causing reaction force F1 and side reaction force F2 at a first point P1 of the lower plate 50 and a second point P2 of the upper plate 70. The reaction force F1 and the side reaction force F2 induce stopping of the movement of the probe 30 at the lower plate 50 and the upper plate 70.

Considering FIGS. 1 and 3, however, the probe 30 incidentally causes unstable movement of the displacement portion 18 between the lower plate 50 and the upper plate 70 due to the lower plate 50 and the upper plate 70 being spaced apart from each other, which prevents the movement of the probe 30 from stopping at the lower plate 50 and the upper plate 70.

Furthermore, the lower plate 50 and the upper plate 70 are spaced apart from each other, and thus fail to prevent the attachment of foreign matter from the external environment to the probe 30, thereby causing difficulty in the movement of the probe 30 at the lower plate 50 and the upper plate 70. In addition, the lower plate 50 and the upper plate 70 are spaced apart from each other, and thus fail to protect the displacement portion 18, thereby rapidly degrading the durability of the displacement portion 18.

### SUMMARY OF THE INVENTION

The present invention has been made in view of the above problems, and it is an object of the present invention to provide a test head suitable for reducing unstable movement of a displacement portion at a lower plate and an upper plate, preventing the attachment of foreign matter from the external environment to a probe through the lower plate and the upper plate, and protecting the displacement portion of the probe through the lower plate and the upper plate in the state in which a probe card and a semiconductor substrate are mounted on an electrical test device during an EDS process.

A test head according to the present invention is configured such that, when a semiconductor substrate is located under a space converter of a probe card, the test head is located between the space converter and the semiconductor substrate so as to be in contact with an electrical pad of the space converter and a substrate pad of the semiconductor substrate, wherein the test head includes a probe located in the form of a pin from the semiconductor substrate toward the space converter, the probe having a displacement portion and an elastic portion located near the space converter and the semiconductor substrate, respectively, and a lower plate and an upper plate sequentially located in a longitudinal direction of the probe, the lower plate and the upper plate being configured to surround the displacement portion, the probe has a “C” shape or an inverted “C” shape at the displacement portion, and the lower plate and the upper plate contact each other around the displacement portion in a direction perpendicular to the longitudinal direction of the probe.

The probe may be configured to be located at the lower plate and the upper plate in at least one and to move relative to the lower plate and the upper plate, when external force is applied to at least one of the space converter and the semiconductor substrate, so as to be electrically connected to the electric pad of the space converter and the substrate pad of the semiconductor substrate.

The displacement portion may have a concave shape on one side of the displacement portion and a convex shape on the other side of the displacement portion on both sides of the displacement portion.

The displacement portion may be configured to have a displacement hole portion formed in the longitudinal direction of the probe and to be relatively curved in a middle region of the displacement hole portion compared to a lower region and an upper region of the displacement hole portion.

The displacement hole portion may have two displacement holes curved over the lower region, the middle region, and the upper region of the displacement hole portion, the two displacement holes being opened so as to have the same length in the longitudinal direction of the probe.

The displacement hole portion may have two displacement holes curved over the lower region, the middle region, and the upper region of the displacement hole portion, the two displacement holes being opened so as to have a larger length near a concave shape of the displacement hole portion than near a convex shape of the displacement hole portion in the longitudinal direction of the probe.

The displacement hole portion may have two displacement holes curved over the lower region, the middle region, and the upper region of the displacement hole portion, the two displacement holes being opened so as to be more biased toward the lower region of the displacement hole portion near a convex shape of the displacement hole portion than near a concave shape of the displacement hole portion in the longitudinal direction of the probe.

The displacement hole portion may have two displacement holes each including a first group extending from the lower region of the displacement hole portion toward one side of the middle region of the displacement hole portion and a second group extending from the other side of the middle region of the displacement hole portion toward the upper region of the displacement hole portion, the two displacement holes being opened so as to have the same length near a concave shape of the displacement hole portion and near a convex shape of the displacement hole portion by group in the longitudinal direction of the probe.

The displacement hole portion may have two displacement holes each including a first group located in the lower region of the displacement hole portion, a second group located in one side of the middle region of the displacement hole portion, a third group located in the other side of the middle region of the displacement hole portion, and a fourth group located in the upper region of the displacement hole portion, the two displacement holes being opened so as to have the same length near a concave shape of the displacement hole portion and near a convex shape of the displacement hole portion by group in the longitudinal direction of the probe.

The displacement hole portion may have two displacement holes each including a first group located in the lower region of the displacement hole portion, a second group located in one side of the middle region of the displacement hole portion, a third group located in the other side of the middle region of the displacement hole portion, and a fourth group located in the upper region of the displacement hole portion, the two displacement holes being opened so as to have different lengths by group in the longitudinal direction of the probe.

The displacement hole portion may have a displacement hole located in the lower region, the middle region, and the upper region of the displacement hole portion, the displacement hole being opened so as to have a larger size in the middle region than in the lower region and the upper region in the longitudinal direction of the probe.

The displacement hole portion may have the displacement hole formed along a curve in each of both side surfaces of the displacement hole portion.

The probe may further include a probing head formed integrally at the displacement portion between the upper plate and the space converter, the probing head being in contact with the electric pad of the space converter, and a probing tip located under the elastic portion, the probing tip being in contact with the substrate pad of the semiconductor substrate.

The middle region of the displacement hole portion may vertically descend from an upper part to a lower part of the displacement portion under the probing head and, when viewed along a reference line abutting the upper part of the displacement portion, may protrude more convexly by a value of 4 to 60 μm from the reference line in a direction perpendicular to the longitudinal direction of the probe.

The lower plate may correspond to the upper plate in a face-to-face manner so as to be in contact with the upper plate.

### BRIEF DESCRIPTION OF THE DRAWINGS

FIG. 1 is a schematic view showing a conventional probe card;

FIG. 2 is a schematic view showing a probe in the probe card of FIG. 1;

FIG. 3 is a schematic view showing the positional relationship between the probe, a lower plate, and an upper plate during an EDS process in the probe card of FIG. 1;

FIG. 4 is a schematic view showing a test head during an EDS process in a probe card according to the present invention;

FIG. 5 is a schematic view showing a probe in the test head of FIG. 4;

FIG. 6 is a schematic view showing a first modification of the probe of FIG. 5;

FIG. 7 is a schematic view showing a second modification of the probe of FIG. 5;

FIG. 8 is a schematic view showing a third modification of the probe of FIG. 5;

FIG. 9 is a schematic view showing a fourth modification of the probe of FIG. 5;

FIG. 10 is a schematic view showing a fifth modification of the probe of FIG. 5;

FIG. 11 is a schematic view showing a sixth modification of the probe of FIG. 5;

FIG. 12 is a schematic view showing the shape of the probe of FIG. 5 in detail;

FIG. 13 is a schematic view showing the shape of the probe of FIG. 7 in detail;

FIG. 14 is a schematic view showing lower and upper plates of FIG. 4 surrounding the probe of FIG. 2, as a comparative example;

FIGS. 15 to 17 are virtual views showing, by simulation, the movement of the probe at the lower and upper plates of FIG. 14 during the EDS process; and

FIGS. 18 to 20 are virtual views showing, by simulation, the movement of the probe at the lower and upper plates of FIG. 4 during the EDS process, as an example.

### DETAILED DESCRIPTION OF THE PREFERRED EMBODIMENTS

Hereinafter, preferred embodiments of the present invention will be described in detail with reference to the accompanying drawings such that the present invention can be easily implemented by a person having ordinary skill in the art to which the present invention pertains.

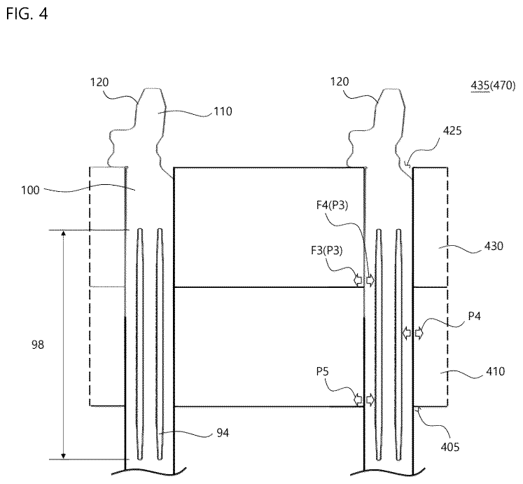

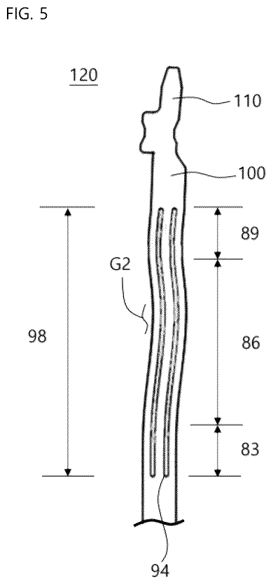

FIG. 4 is a schematic view showing a test head during an EDS process in a probe card according to the present invention, and FIG. 5 is a schematic view showing a probe in the test head of FIG. 4.

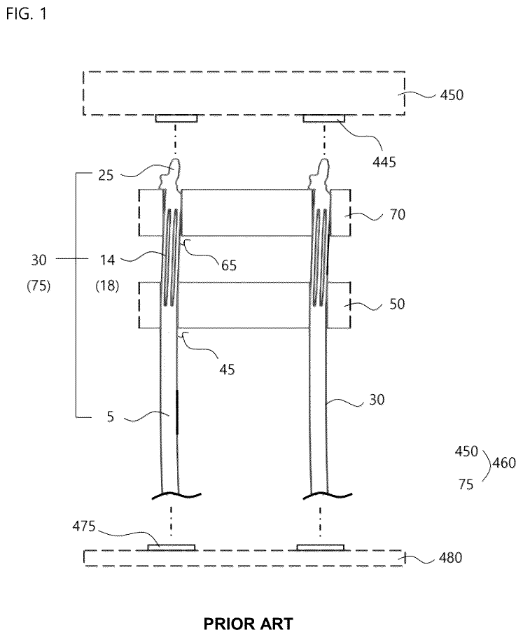

In this case, FIGS. 4 and 5 are described with reference to FIG. 1.

Referring to FIGS. 4 to 5, the test head 435 according to the present invention is configured such that, when a semiconductor substrate 480 (FIG. 1) is located under a space converter 450 (FIG. 1) of the probe card 470, the test head is located between the space converter 450 and the semiconductor substrate 480 so as to be in contact with an electric pad 445 of the space converter 450 and a substrate pad 475 of the semiconductor substrate 480.

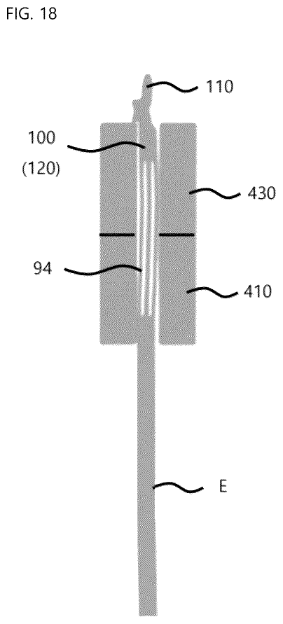

To this end, the test head 435 includes a probe 120 located in the form of a pin from the semiconductor substrate 480 toward the space converter 450, the probe having a displacement portion 100 and an elastic portion E (FIG. 18) located near the space converter 450 and the semiconductor substrate 480, respectively, and a lower plate 410 and an upper plate 430 sequentially located in a longitudinal direction of the probe 120, the lower plate and the upper plate being configured to surround the displacement portion 100.

Here, the probe 120 has a “C” shape or an inverted “C” shape G2 at the displacement portion 100 in FIG. 5. The lower plate 410 and the upper plate 430 contact each other around the displacement portion 100 in a direction perpendicular to the longitudinal direction of the probe 120 in FIG. 4. That is, the lower plate 410 corresponds to the upper plate 430 in a face-to-face manner and contacts the upper plate 430.

Considering FIG. 4, the probe 120 is located in a lower guide hole 405 of the lower plate 410 and an upper guide hole 425 of the upper plate 430 in at least one, and when external force is applied to at least one of the space converter 450 and the semiconductor substrate 480, the probe moves relative to the lower plate 410 and the upper plate 430 and is electrically connected to the electric pad 445 of the space converter 450 and the substrate pad 475 of the semiconductor substrate 480.

In FIG. 5, the displacement portion 100 has a concave shape on one side of the displacement portion 100 and a convex shape on the other side of the displacement portion 100 on both sides of the displacement portion 100. In FIGS. 4 and 5, the displacement portion 100 has a displacement hole portion 98 formed in the longitudinal direction of the probe 120, and is relatively curved in a middle region 86 of the displacement hole portion 98 compared to a lower region 83 and an upper region 89 of the displacement hole portion 98.

In FIGS. 4 and 5, the displacement hole portion 98 has two displacement holes 94 that are curved over the lower region, the middle region, and the upper region of the displacement hole portion 98 and are opened so as to have the same length in the longitudinal direction of the probe 120.

In addition, In FIG. 5, the displacement hole portion 98 has displacement holes 94 formed along the curve in both side surfaces of the displacement hole portion 98.

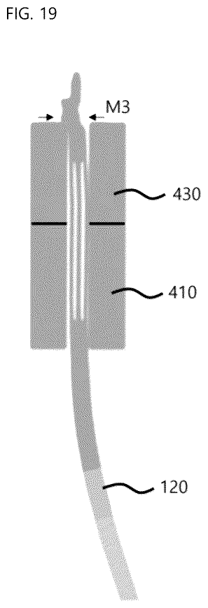

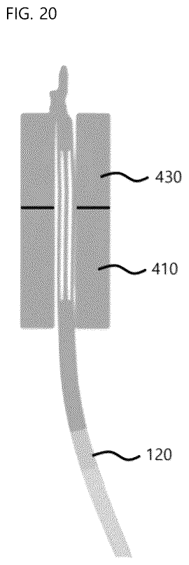

Meanwhile, considering FIGS. 4, 5, and 18 to 20, the probe 120 further includes a probing head 110 formed integrally at the displacement portion 100 between the upper plate 430 and the space converter 450, the probing head being in contact with the electric pad 445 of the space converter 450, and a probing tip (not shown) located under the elastic portion E, the probing tip being in contact with the substrate pad 475 of the semiconductor substrate 480.

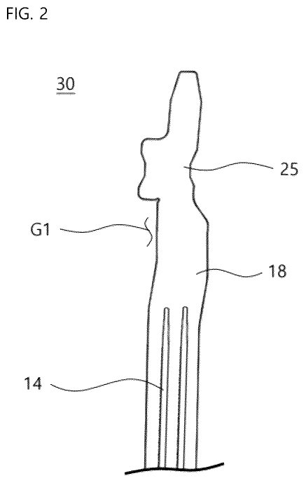

Here, the probing head 110 has the same shape as the probing head 25 of FIG. 2.

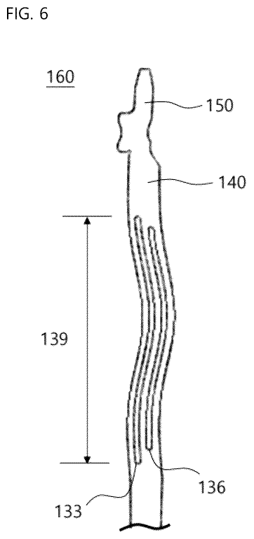

FIG. 6 is a schematic view showing a first modification of the probe of FIG. 5.

Referring to FIG. 6, the probe 160 according to the first modification of the present invention has a similar shape to the probe 120 of FIG. 5, but a displacement hole portion 139 of a displacement portion 140 of the probe 160 has a different shape from the displacement hole portion 98 of the displacement portion 100 of the probe 120 of FIG. 5.

More specifically, the displacement hole portion 139 has two displacement holes 133 and 136 that are curved over a lower region, a middle region, and an upper region of the displacement hole portion 139 and are opened so as to have a larger length near the concave shape of the displacement hole portion 139 than near the convex shape of the displacement hole portion 139 in the longitudinal direction of the probe 160.

Here, a probing head 150 has the same shape as the probing head 25 of FIG. 5.

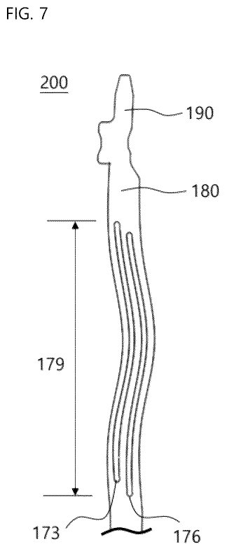

FIG. 7 is a schematic view showing a second modification of the probe of FIG. 5.

Referring to FIG. 7, the probe 200 according to the second modification of the present invention has a similar shape to the probe 120 of FIG. 5, but a displacement hole portion 179 of a displacement portion 180 of the probe 200 has a different shape from the displacement hole portion 98 of the displacement portion 100 of the probe 120 of FIG. 5.

More specifically, the displacement hole portion 179 has two displacement holes 173 and 176 that are curved over a lower region, a middle region, and an upper region of the displacement hole portion 179 and are opened so as to be more biased toward the lower region of the displacement hole portion 179 near the convex shape of the displacement hole portion 179 than near the concave shape of the displacement hole portion 179 in the longitudinal direction of the probe 200.

Here, a probing head 190 has the same shape as the probing head 25 of FIG. 5.

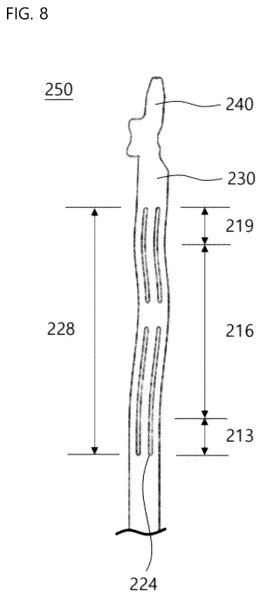

FIG. 8 is a schematic view showing a third modification of the probe in FIG. 5.

Referring to FIG. 8, the probe 250 according to the third modification of the present invention has a similar shape to the probe 120 of FIG. 5, but a displacement hole portion 228 of a displacement portion 230 of the probe 250 has a different shape from the displacement hole portion 98 of the displacement portion 100 of the probe 120 of FIG. 5.

More specifically, the displacement hole portion 228 has two displacement holes 224 that each include a first group extending from a lower region 213 of the displacement hole portion 228 toward one side of a middle region 216 of the displacement hole portion 228 and a second group extending from the other side of the middle region 216 of the displacement hole portion 228 toward an upper region 219 of the displacement hole portion 228 and are opened so as to have the same length near the concave shape of the displacement hole portion 228 and near the convex shape of the displacement hole portion 228 by group in the longitudinal direction of the probe 250.

Here, a probing head 240 has the same shape as the probing head 25 of FIG. 5.

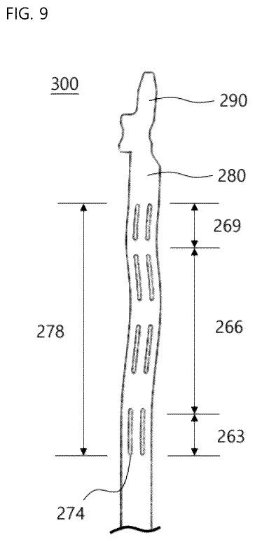

FIG. 9 is a schematic view showing a fourth modification of the probe of FIG. 5.

Referring to FIG. 9, the probe 300 according to the fourth modification of the present invention has a similar shape to the probe 120 of FIG. 5, but a displacement hole portion 278 of a displacement portion 280 of the probe 300 has a different shape from the displacement hole portion 98 of the displacement portion 100 of the probe 120 of FIG. 5.

More specifically, the displacement hole portion 278 has two displacement holes 274 that each include a first group located in a lower region 263 of the displacement hole portion 278, a second group located in one side of a middle region 266 of the displacement hole portion 278, a third group located in the other side of the middle region 266 of the displacement hole portion 278, and a fourth group located in an upper region 269 of the displacement hole portion 278 and are opened so as to have the same length near the concave shape of the displacement hole portion 278 and near the convex shape of the displacement hole portion 278 by group in the longitudinal direction of the probe 300.

Here, a probing head 290 has the same shape as the probing head 25 of FIG. 5.

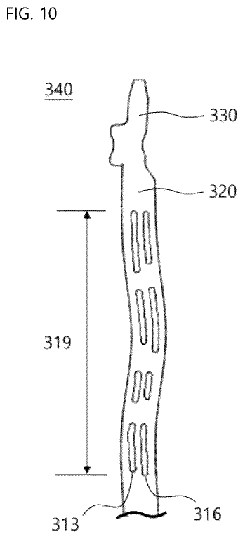

FIG. 10 is a schematic view showing a fifth modification of the probe of FIG. 5.

Referring to FIG. 10, the probe 340 according to the fifth modification of the present invention has a similar shape to the probe 120 of FIG. 5, but a displacement hole portion 319 of a displacement portion 320 of the probe 340 has a different shape from the displacement hole portion 98 of the displacement portion 100 of the probe 120 of FIG. 5.

More specifically, the displacement hole portion 319 has two displacement holes 274 that each include a first group located in a lower region of the displacement hole portion 319, a second group located in one side of a middle region of the displacement hole portion 319, a third group located in the other side of the middle region of the displacement hole portion 319, and a fourth group located in an upper region of the displacement hole portion 319 and are opened so as to have different lengths by group in the longitudinal direction of the probe 340.

Here, a probing head 330 has the same shape as the probing head 25 of FIG. 5.

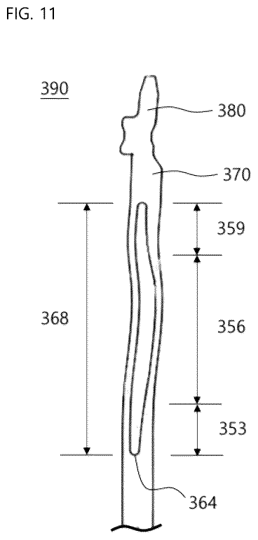

FIG. 11 is a schematic view showing a sixth modification of the probe of FIG. 5.

Referring to FIG. 11, the probe 390 according to the sixth modification of the present invention has a similar shape to the probe 120 of FIG. 5, but a displacement hole portion 368 of a displacement portion 370 of the probe 390 has a different shape from the displacement hole portion 98 of the displacement portion 100 of the probe 120 of FIG. 5.

More specifically, the displacement hole portion 368 has a displacement hole 364 that is located in a lower region 353, a middle region 356, and an upper region 359 of the displacement hole portion 368 and is opened so as to have a larger size in the middle region 356 than in the lower region 353 and the upper region 359 in the longitudinal direction of the probe 390.

Here, a probing head 380 has the same shape as the probing head 25 of FIG. 5.

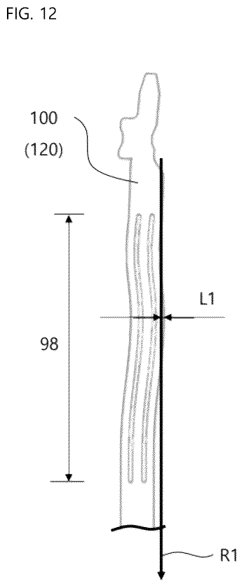

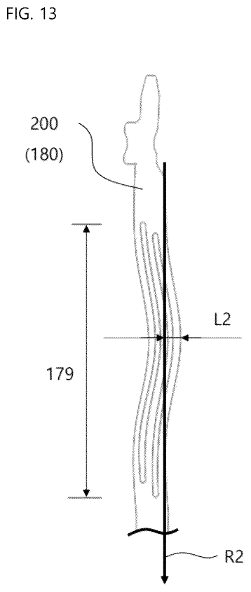

FIG. 12 is a schematic view showing the shape of the probe of FIG. 5 in detail, and FIG. 13 is a schematic view showing the shape of the probe of FIG. 7 in detail.

Referring to FIGS. 12 and 13, the middle region of the displacement hole portion 98 or 179 vertically descends from an upper part to a lower part of the displacement portion 100 or 200 under the probing head 110 and, when viewed along a reference line R1 or R2 abutting the upper part of the displacement portion 100 or 200, protrudes more convexly by a predetermined value L1 or L2 of 4 to 60 μm from the reference line R1 or R2 in a direction perpendicular to the longitudinal direction of the probe 120 or 180.

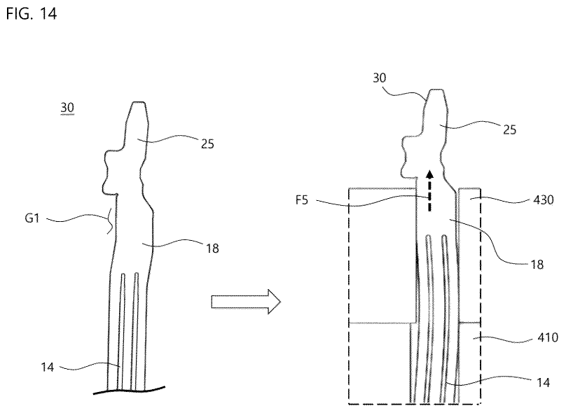

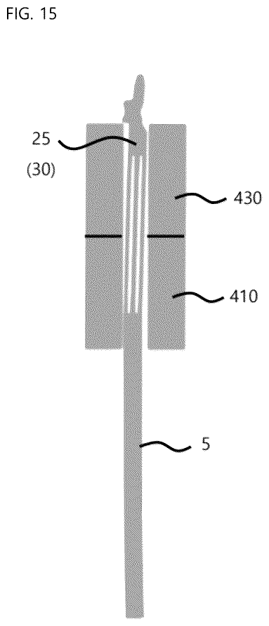

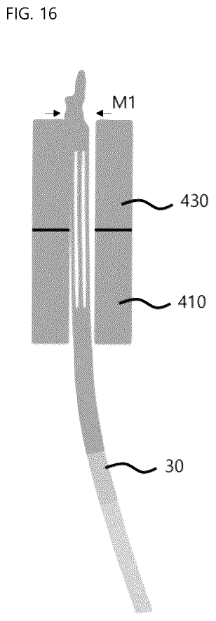

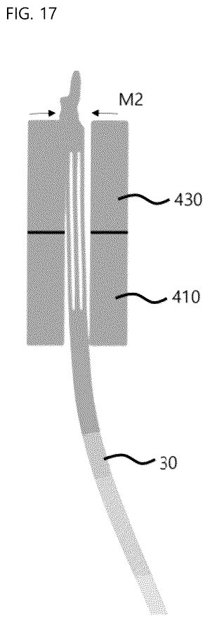

FIG. 14 is a schematic view showing the lower and upper plates of FIG. 4 surrounding the probe of FIG. 2, as a comparative example, and FIGS. 15 to 17 are virtual views showing, by simulation, the movement of the probe at the lower and upper plates of FIG. 14 during the EDS process.

Referring to FIGS. 14 to 17, the probe 30 of FIG. 2 has a “U”-shaped groove G1 formed in the displacement portion 18 and the probing head 25 along one side wall of the probe 30. The probe 30 connects both side walls located around the displacement hole 14 of the displacement portion 18 and both side walls curved into the “U”-shaped groove G1 so as to be at an angle to each other.

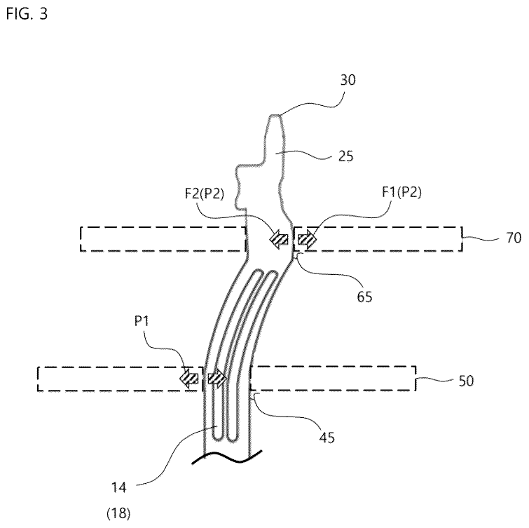

When the probe 30 is surrounded by the lower plate 410 and the upper plate 430 of FIG. 4, the probe 30 moves in the lower guide hole 405 of the lower plate 410 and the upper guide hole 425 of the upper plate 430 during the EDS process to cause reaction force F1 (FIG. 3) and side reaction force F2 (FIG. 3) from at least one of both side walls located around the displacement hole 14 and both side walls curved into the “U”-shaped groove G1.

Since, although stopping of the movement of the probe 30 at the lower plate 410 and the upper plate 430 is induced using the reaction force F1 and the side reaction force F2, the frictional force between the probe 30 and the lower plate 410 and between the probe 30 and the upper plate 430 is reduced by the reaction force F1 and the side reaction force F2, the force F5 that separates the probing head 25 from the upper plate 430 may be easily applied to the probe against the frictional force, as shown in FIG. 14.

More specifically, as shown in FIGS. 15 to 17, the probe 30 performs unstable side-to-side movement M1 or M2 through the displacement portion 25 at the lower plate 410 and the upper plate 430 when the elastic portion 5 buckles through the EDS process. Consequently, even if the probe 30 causes the reaction force F1 and the side reaction force F2 at the lower plate 410 and the upper plate 430, the friction force between the probe 30 and the lower plate 410 and between the probe 30 and the upper plate 430 is reduced due to the number of points P1 and P2 of the reaction force F1 and the unstable movement M1 or M2 of the displacement portion.

FIGS. 18 to 20 are virtual views showing, by simulation, the movement of the probe at the lower and upper plates of FIG. 4 during the EDS process, as an example.

Referring to FIGS. 18 to 20, the probe 120 of FIG. 4 or 5 has a “C” shape or an inverted “C” shape G2 at the displacement portion 100. In FIG. 4, the displacement portion 120 of the probe 120 is in wider contact with the lower plate 410 and the upper plate 430 than the displacement portion 25 of the probe 30 of FIG. 2.

When the probe 120 is surrounded by the lower plate 410 and the upper plate 430 of FIG. 4, the probe 120 causes reaction force F3 (FIG. 4) and side reaction force F4 (FIG. 4) from at least three points P3, P4, and P5 (FIG. 4) of both “C”-shaped side walls located around the displacement hole 94 while moving in the lower guide hole 405 of the lower plate 410 and the upper guide hole 425 of the upper plate 430 during the EDS process.

At this time, the frictional force is generated between the probe 30 and the lower plate 410 and between the probe 30 and the upper plate 430 such that stopping of the movement of the probe 30 at the lower plate 410 and the upper plate 430 is induced using the reaction force F3 and the side reaction F4, whereby the probing head 25 is in continuous contact with the upper plate 430 during the EDS process.

In addition, the behavior time of the probe 120 in FIGS. 18 to 20 is the same as the behavior time of the probe 30 in FIGS. 15 to 17. In this case, as shown in FIGS. 18 to 20, the probe 120 only performs stable movement M3 from side to side through the displacement portion 25 at the lower plate 410 and the upper plate 430 when the elastic portion E buckles during the EDS process.

Consequently, the frictional force between the probe 120 and the lower plate 410 and between the probe 120 and the upper plate 430 is generated through the reaction force F3 and the side reaction force F4 at the lower plate 410 and the upper plate 430 so as to be greater than in the case of the probe 30 of FIG. 14 or 15.

As is apparent from the above description, a test head according to the present invention is configured such that, when a semiconductor substrate is located under a space converter of a probe card, the test head is located between the space converter and the semiconductor substrate so as to be in contact with an electrical pad of the space converter and a substrate pad of the semiconductor substrate.

The test head includes a probe having an elastic portion and a displacement portion sequentially located between the semiconductor substrate and the space converter and lower and upper plates that are sequentially located in a longitudinal direction of the probe and surround the displacement portion.

One elastic hole is formed in the elastic portion of the probe, two displacement holes are formed in the displacement portion of the probe, and the lower and upper plates in contact with each other are located around the displacement portion of the probe.

Consequently, it is possible to reduce unstable movement of the displacement portion at the lower plate and the upper plate, to prevent the attachment of foreign matter from the external environment to the displacement portion of the probe using the lower plate and the upper plate, and to protect the displacement portion of the probe through the lower plate and the upper plate, whereby it is possible to maintain durability of the displacement portion during the lifespan of the probe.

What is claimed is:

1. A test head configured such that, when a semiconductor substrate is located under a space converter of a probe card, the test head is located between the space converter and the semiconductor substrate so as to be in contact with an electrical pad of the space converter and a substrate pad of the semiconductor substrate, the test head comprising:
a probe located in the form of a pin from the semiconductor substrate toward the space converter, the probe having a displacement portion and an elastic portion located near the space converter and the semiconductor substrate, respectively; and
a lower plate and an upper plate sequentially located in a longitudinal direction of the probe, the lower plate and the upper plate being configured to surround the displacement portion, wherein
the probe has a “C” shape or an inverted “C” shape at the displacement portion, and
the lower plate and the upper plate contact each other around the displacement portion in a direction perpendicular to the longitudinal direction of the probe.

2. The test head according to claim 1, wherein the probe is configured:
to be located at the lower plate and the upper plate in at least one; and
to move relative to the lower plate and the upper plate, when external force is applied to at least one of the space converter and the semiconductor substrate, so as to be electrically connected to the electric pad of the space converter and the substrate pad of the semiconductor substrate.

3. The test head according to claim 1, wherein the displacement portion has a concave shape on one side of the displacement portion and a convex shape on the other side of the displacement portion on both sides of the displacement portion.

4. The test head according to claim 1, wherein the displacement portion is configured:
to have a displacement hole portion formed in the longitudinal direction of the probe; and
to be relatively curved in a middle region of the displacement hole portion compared to a lower region and an upper region of the displacement hole portion.

5. The test head according to claim 4, wherein the displacement hole portion has two displacement holes curved over the lower region, the middle region, and the upper region of the displacement hole portion, the two displacement holes being opened so as to have the same length in the longitudinal direction of the probe.

6. The test head according to claim 4, wherein the displacement hole portion has two displacement holes curved over the lower region, the middle region, and the upper region of the displacement hole portion, the two displacement holes being opened so as to have a larger length near a concave shape of the displacement hole portion than near a convex shape of the displacement hole portion in the longitudinal direction of the probe.

7. The test head according to claim 4, wherein the displacement hole portion has two displacement holes curved over the lower region, the middle region, and the upper region of the displacement hole portion, the two displacement holes being opened so as to be more biased toward the lower region of the displacement hole portion near a convex shape of the displacement hole portion than near a concave shape of the displacement hole portion in the longitudinal direction of the probe.

8. The test head according to claim 4, wherein the displacement hole portion has two displacement holes each comprising a first group extending from the lower region of the displacement hole portion toward one side of the middle region of the displacement hole portion and a second group extending from the other side of the middle region of the displacement hole portion toward the upper region of the displacement hole portion, the two displacement holes being opened so as to have the same length near a concave shape of the displacement hole portion and near a convex shape of the displacement hole portion by group in the longitudinal direction of the probe.

9. The test head according to claim 4, wherein the displacement hole portion has two displacement holes each comprising a first group located in the lower region of the displacement hole portion, a second group located in one side of the middle region of the displacement hole portion, a third group located in the other side of the middle region of the displacement hole portion, and a fourth group located in the upper region of the displacement hole portion, the two displacement holes being opened so as to have the same length near a concave shape of the displacement hole portion and near a convex shape of the displacement hole portion by group in the longitudinal direction of the probe.

10. The test head according to claim 4, wherein the displacement hole portion has two displacement holes each comprising a first group located in the lower region of the displacement hole portion, a second group located in one side of the middle region of the displacement hole portion, a third group located in the other side of the middle region of the displacement hole portion, and a fourth group located in the upper region of the displacement hole portion, the two displacement holes being opened so as to have different lengths by group in the longitudinal direction of the probe.

11. The test head according to claim 4, wherein the displacement hole portion has a displacement hole located in the lower region, the middle region, and the upper region of the displacement hole portion, the displacement hole being opened so as to have a larger size in the middle region than in the lower region and the upper region in the longitudinal direction of the probe.

12. The test head according to claim 4, wherein the displacement hole portion has the displacement hole formed along a curve in each of both side surfaces of the displacement hole portion.

13. The test head according to claim 4, wherein the probe further comprises:
a probing head formed integrally at the displacement portion between the upper plate and the space converter, the probing head being in contact with the electric pad of the space converter; and
a probing tip located under the elastic portion, the probing tip being in contact with the substrate pad of the semiconductor substrate.

14. The test head according to claim 13, wherein the middle region of the displacement hole portion vertically descends from an upper part to a lower part of the displacement portion under the probing head and, when viewed along a reference line abutting the upper part of the displacement portion, protrudes more convexly by a value of 4 to 60 μm from the reference line in a direction perpendicular to the longitudinal direction of the probe.

15. The test head according to claim 4, wherein the lower plate corresponds to the upper plate in a face-to-face manner so as to be in contact with the upper plate.
